(19) United States
(12) Patent Application Publication
(10) Pub. No.: US 2025/0053699 A1
(43) Pub. Date: Feb. 13, 2025

(54) ENHANCING THE ELECTRON PAIR APPROXIMATION WITH MEASUREMENTS FOR THE VARIATIONAL QUANTUM EIGENSOLVER

(71) Applicants: Hyundai Motor Company, Seoul (KR); Kia Corporation, Seoul (KR); IonQ, Inc., College Park, MD (US)

(72) Inventors: Kyujin Shin, Gunpo (KR); Woomin Kyoung, Yongin (KR); Joshua J. Goings, Auburn, WA (US); Luning Zhao, Sunnyvale, CA (US); Qingfeng Wang, Durham, NC (US)

(21) Appl. No.: 18/447,792

(22) Filed: Aug. 10, 2023

(51) Int. Cl. G06F 30/20

(52) U.S. Cl. CPC G06F 30/20

(57) ABSTRACT

Systems and methods for enhancing accuracy of electron pair approximation using non-bosonic perturbation (PT2) correction are provided. The method may comprise generating a unitary pair coupled cluster double (upCCD) Ansatz to determine geometry coordinates of a molecule, inputting, using a graphical user interface, the geometry coordinates of the molecule, performing, using a processor of a computing device comprising the processor and a memory, orbital optimization to generate an orbital optimization upCCD (oo-upCCD) comprising an energy calculation, and performing, using the processor, energy correction on the energy calculation of the oo-upCCD based on a second order perturbation theory (PT2), generating a PT2 correction energy value of the molecule. The computing device may comprise a quantum computer.

### BACKGROUND

### Technical Field

Embodiments of the present disclosure relate to systems and methods for enhancing accuracy of electron pair approximation using non-bosonic perturbation (PT2) correction.

### Background

The unitary pair coupled cluster double (upCCD) is an efficient Ansatz used in the Variational Quantum Eigensolver (VQE) algorithm to perform quantum chemistry simulations on quantum computers. However, upCCD introduces an approximation that restricts all electrons in a simulated chemical system to be paired. Such an approximation leads to highly efficient quantum circuit compilation for upCCD, but it also results in a large number of errors in the predicted energy. For example, in Li₂O, the calculated energy error for upCCD-VQE is approximately 100 millihartrees, as shown, e.g., in graph 100 of FIG. 1. FIG. 1 illustrates an example graphical representation of dissociation of Li₂O, comparing prior VQE calculation (upCCD and orbital optimization up-CCD (oo-upCCD)) and full configuration interaction theoretical value (FCI).

Therefore, how to go beyond the electron pair approximation to improve the accuracy of upCCD becomes a pressing question.

One possible direction is to account for “broken-pair” energy contributions by directly implementing them with quantum circuits. Efficient circuit compilation has been developed to do so. However, by doing so, one immediately loses two advantages of upCCD. First, that of shallow circuits compilation, in which the number of entangling gates in upCCD scales as N² with respect to system size, which is manageable for large systems on today's quantum computers. Second, that of constant energy measurement overhead, in which only three circuits need to run to measure energy for upCCD, which is independent of the system size.

### SUMMARY

According to an object of the present disclosure, a method for enhancing accuracy of electron pair approximation using non-bosonic perturbation (PT2) correction is provided. The method may comprise generating a unitary pair coupled cluster double (upCCD) Ansatz to determine geometry coordinates of a molecule, inputting, using a graphical user interface, the geometry coordinates of the molecule, performing, using a processor of a computing device comprising the processor and a memory, orbital optimization to generate an orbital optimization upCCD (oo-upCCD) comprising an energy calculation, and performing, using the processor, energy correction on the energy calculation of the oo-upCCD based on a second order perturbation theory (PT2), generating a PT2 correction energy value of the molecule.

According to an exemplary embodiment, the method may further comprise, using the processor, reporting the PT2 correction energy value of the molecule.

According to an exemplary embodiment, the performing the orbital optimization may comprise computing an orbital gradient and a Hessian.

According to an exemplary embodiment, the performing the orbital optimization may comprise performing a Newton-Raphson method and updating one or more orbital parameters.

According to an exemplary embodiment, the performing the orbital optimization may comprise performing the orbital optimization until the energy calculation of the oo-upCCD is converged.

According to an exemplary embodiment, the computing device may comprise a quantum computer.

According to an object of the present disclosure, a system for enhancing accuracy of electron pair approximation using non-bosonic perturbation (PT2) correction is provided. The system may comprise a computing device, comprising a processor, a memory, and a graphical user interface. The processor may be configured to generate a upCCD Ansatz to determine geometry coordinates of a molecule. The graphical user interface may be configured to receive, as input, the geometry coordinates of the molecule. The processor may be further configured to perform orbital optimization to generate an oo-upCCD comprising an energy calculation, and perform energy correction on the energy calculation of the oo-upCCD based on a second order perturbation theory (PT2), generating a PT2 correction energy value of the molecule.

According to an exemplary embodiment, the processor may be further configured to report the PT2 correction energy value of the molecule.

According to an exemplary embodiment, the processor, in performing the orbital optimization, may be configured to compute an orbital gradient and a Hessian.

According to an exemplary embodiment, the processor, in performing the orbital optimization, may be configured to perform a Newton-Raphson method and update one or more orbital parameters.

According to an exemplary embodiment, the processor, in performing the orbital optimization, may be configured to perform the orbital optimization until the energy calculation of the oo-upCCD is converged.

According to an exemplary embodiment, the computing device may comprise a quantum computer.

According to an object of the present disclosure, a system for enhancing accuracy of electron pair approximation using non-bosonic perturbation (PT2) correction is provided. The system may comprise a computing device, comprising a processor, a memory, and a graphical user interface. The memory may be configured to store programming instructions that, when executed by the processor, are configured to cause the processor to generate a upCCD Ansatz to determine geometry coordinates of a molecule, enable the graphical user interface to receive, as input, the geometry coordinates of the molecule, perform orbital optimization to generate an oo-upCCD comprising an energy calculation, and perform energy correction on the energy calculation of the oo-upCCD based on a second order perturbation theory (PT2), generating a PT2 correction energy value of the molecule.

According to an exemplary embodiment, the programming instructions, when executed by the processor, may be further configured to cause the processor to report the PT2 correction energy value of the molecule.

According to an exemplary embodiment, the programming instructions, when executed by the processor, may be further configured to cause the processor, in performing the orbital optimization, to compute an orbital gradient and a Hessian.

According to an exemplary embodiment, the programming instructions, when executed by the processor, may be further configured to cause the processor, in performing the orbital optimization, to perform a Newton-Raphson method and update one or more orbital parameters.

According to an exemplary embodiment, the programming instructions, when executed by the processor, may be further configured to cause the processor, in performing the orbital optimization, to perform the orbital optimization until the energy calculation of the oo-upCCD is converged.

According to an exemplary embodiment, the computing device may comprise a quantum computer.

### BRIEF DESCRIPTION OF THE DRAWINGS

The accompanying drawings, which are incorporated in and form a part of the Description of Embodiments, illustrate various non-limiting and non-exhaustive embodiments of the subject matter and, together with the Detailed Description, serve to explain principles of the subject matter discussed below. Unless specifically noted, the drawings referred to in this Brief Description of Drawings should be understood as not being drawn to scale and like reference numerals refer to like parts throughout the various figures unless otherwise specified.

FIG. 1 illustrates a graphical representation of dissociation of Li₂O, comparing prior Variational Quantum Eigensolver (VQE) calculation (unitary pair coupled cluster double (upCCD) and orbital optimization up-CCD (oo-upCCD)) and full configuration interaction theoretical value (FCI), according to an exemplary embodiment of the present disclosure.

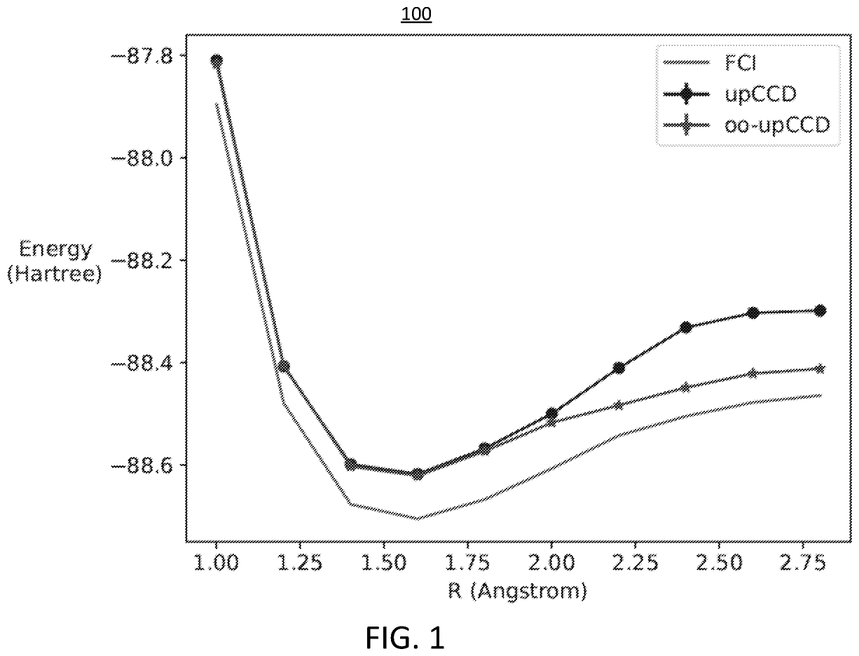

FIG. 2 illustrates a flow chart of a method for performing an algorithm to enhance the accuracy of electron pair (seniority-zero) approximation using non-bosonic perturbation (PT2) correction, according to an exemplary embodiment of the present disclosure.

FIG. 3 illustrates a graphical representation of dissociation of Li₂O, according to an exemplary embodiment of the present disclosure.

FIG. 4 illustrates a graphical representation of CH₂OH⁺→HCO⁺+H₂ reaction energy prediction, in accordance with an exemplary embodiment of the present disclosure.

FIG. 5 illustrates example elements of a computing device, according to an exemplary embodiment of the present disclosure.

### DETAILED DESCRIPTION

The following Description of Embodiments is merely provided by way of example and not of limitation. Furthermore, there is no intention to be bound by any expressed or implied theory presented in the preceding background or in the following Detailed Description.

Reference will now be made in detail to various exemplary embodiments of the subject matter, examples of which are illustrated in the accompanying drawings. While various embodiments are discussed herein, it will be understood that they are not intended to limit to these embodiments. On the contrary, the presented embodiments are intended to cover alternatives, modifications, and equivalents, which may be included within the spirit and scope the various embodiments as defined by the appended claims. Furthermore, in this Detailed Description, numerous specific details are set forth in order to provide a thorough understanding of embodiments of the present subject matter. However, embodiments may be practiced without these specific details. In other instances, well known methods, procedures, components, and circuits have not been described in detail as not to unnecessarily obscure aspects of the described embodiments.

Some portions of the detailed descriptions which follow are presented in terms of procedures, logic blocks, processing, and other symbolic representations of operations on data within an electrical device. These descriptions and representations are the means used by those skilled in the data processing arts to most effectively convey the substance of their work to others skilled in the art. In the present application, a procedure, logic block, process, or the like, is conceived to be one or more self-consistent procedures or instructions leading to a desired result. The procedures are those requiring physical manipulations of physical quantities. Usually, although not necessarily, these quantities may take the form of electrical or magnetic signals capable of being stored, transferred, combined, compared, and otherwise manipulated in an electronic system, device, and/or component.

It should be borne in mind, however, that these and similar terms are to be associated with the appropriate physical quantities and are merely convenient labels applied to these quantities. Unless specifically stated otherwise as apparent from the following discussions, it is appreciated that throughout the description of embodiments, discussions utilizing terms such as “determining,” “communicating,” “taking,” “comparing,” “monitoring,” “calibrating,” “estimating,” “initiating,” “providing,” “receiving,” “controlling,” “transmitting,” “isolating,” “generating,” “aligning,” “synchronizing,” “identifying,” “maintaining,” “displaying,” “switching,” or the like, refer to the actions and processes of an electronic item such as: a processor, a sensor processing unit (SPU), a processor of a sensor processing unit, an application processor of an electronic device/system, or the like, or a combination thereof. The item manipulates and transforms data represented as physical (electronic and/or magnetic) quantities within the registers and memories into other data similarly represented as physical quantities within memories or registers or other such information storage, transmission, processing, or display components.

It is understood that the term “quantum computer” refers to a device that performs quantum computing. Quantum computing is computing using quantum-mechanical phenomena, such as superposition and entanglement. Quantum computers differ from traditional computers that are based on transistors, as such traditional computers require that data be encoded into binary digits (bits), each of which is always in one of two definite states (0 or 1). In contrast to traditional computers, quantum computers use quantum bits, which can be in superpositions of states. A quantum computer maintains a sequence of qubits, where a single qubit can represent a one, a zero, or any quantum superposition of those two qubit states. A pair of qubits can be in any quantum superposition of 4 states, and three qubits in any superposition of 8 states. A quantum computer with n qubits can generally be in an arbitrary superposition of up to 2 ^n different states simultaneously, whereas a traditional computer can only be in one of these states at any one time. A quantum Turing machine is a theoretical model of such a computer.

The terminology used herein is for the purpose of describing particular embodiments only and is not intended to be limiting of the disclosure. As used herein, the singular forms “a,” “an” and “the” are intended to include the plural forms as well, unless the context clearly indicates otherwise. These terms are merely intended to distinguish one component from another component, and the terms do not limit the nature, sequence or order of the constituent components. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Throughout the specification, unless explicitly described to the contrary, the word “comprise” and variations such as “comprises” or “comprising” will be understood to imply the inclusion of stated elements but not the exclusion of any other elements. In addition, the terms “unit”, “-er”, “-or”, and “module” described in the specification mean units for processing at least one function and operation, and can be implemented by hardware components or software components and combinations thereof.

Although exemplary embodiment is described as using a plurality of units to perform the exemplary process, it is understood that the exemplary processes may also be performed by one or plurality of modules. Additionally, it is understood that the term controller/control unit refers to a hardware device that includes a memory and a processor and is specifically programmed to execute the processes described herein. The memory is configured to store the modules and the processor is specifically configured to execute said modules to perform one or more processes which are described further below.

Further, the control logic of the present disclosure may be embodied as non-transitory computer readable media on a computer readable medium containing executable program instructions executed by a processor, controller or the like. Examples of computer readable media include, but are not limited to, ROM, RAM, compact disc (CD)-ROMs, magnetic tapes, floppy disks, flash drives, smart cards and optical data storage devices. The computer readable medium can also be distributed in network coupled computer systems so that the computer readable media is stored and executed in a distributed fashion, e.g., by a telematics server or a Controller Area Network (CAN).

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about”.

Embodiments described herein may be discussed in the general context of processor-executable instructions residing on some form of non-transitory processor-readable medium, such as program modules, executed by one or more computers or other devices. Generally, program modules include routines, programs, objects, components, data structures, etc., that perform particular tasks or implement particular abstract data types. The functionality of the program modules may be combined or distributed as desired in various embodiments.

In the figures, a single block may be described as performing a function or functions; however, in actual practice, the function or functions performed by that block may be performed in a single component or across multiple components, and/or may be performed using hardware, using software, or using a combination of hardware and software. To clearly illustrate this interchangeability of hardware and software, various illustrative components, blocks, modules, logic, circuits, and steps have been described generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure. Also, the example device vibration sensing system and/or electronic device described herein may include components other than those shown, including well-known components.

Various techniques described herein may be implemented in hardware, software, firmware, or any combination thereof, unless specifically described as being implemented in a specific manner. Any features described as modules or components may also be implemented together in an integrated logic device or separately as discrete but interoperable logic devices. If implemented in software, the techniques may be realized at least in part by a non-transitory processor-readable storage medium comprising instructions that, when executed, perform one or more of the methods described herein. The non-transitory processor-readable data storage medium may form part of a computer program product, which may include packaging materials.

The non-transitory processor-readable storage medium may comprise random access memory (RAM) such as synchronous dynamic random access memory (SDRAM), read only memory (ROM), non-volatile random access memory (NVRAM), electrically erasable programmable read-only memory (EEPROM), FLASH memory, other known storage media, and the like. The techniques additionally, or alternatively, may be realized at least in part by a processor-readable communication medium that carries or communicates code in the form of instructions or data structures and that can be accessed, read, and/or executed by a computer or other processor.

Various embodiments described herein may be executed by one or more processors, such as one or more motion processing units (MPUs), sensor processing units (SPUs), host processor(s) or core(s) thereof, digital signal processors (DSPs), general purpose microprocessors, application specific integrated circuits (ASICs), application specific instruction set processors (ASIPs), field programmable gate arrays (FPGAs), a programmable logic controller (PLC), a complex programmable logic device (CPLD), a discrete gate or transistor logic, discrete hardware components, or any combination thereof designed to perform the functions described herein, or other equivalent integrated or discrete logic circuitry. The term “processor,” as used herein may refer to any of the foregoing structures or any other structure suitable for implementation of the techniques described herein. As employed in the subject specification, the term “processor” can refer to substantially any computing processing unit or device comprising, but not limited to comprising, single-core processors; single-processors with software multithread execution capability; multi-core processors; multi-core processors with software multithread execution capability; multi-core processors with hardware multithread technology; parallel platforms; and parallel platforms with distributed shared memory. Moreover, processors can exploit nano-scale architectures such as, but not limited to, molecular and quantum-dot based transistors, switches and gates, in order to optimize space usage or enhance performance of user equipment. A processor may also be implemented as a combination of computing processing units.

In addition, in some aspects, the functionality described herein may be provided within dedicated software modules or hardware modules configured as described herein. Also, the techniques could be fully implemented in one or more circuits or logic elements. A general purpose processor may be a microprocessor, but in the alternative, the processor may be any processor, controller, microcontroller, or state machine. A processor may also be implemented as a combination of computing devices, e.g., a combination of an SPU/MPU and a microprocessor, a plurality of microprocessors, one or more microprocessors in conjunction with an SPU core, MPU core, or any other such configuration. One or more components of an SPU or electronic device described herein may be embodied in the form of one or more of a “chip,” a “package,” an Integrated Circuit (IC).

Embodiments of the present disclosure pertain to an approach that improves the accuracy of unitary pair coupled cluster double (upCCD) based on measurements and second order perturbation theory. Starting from the upCCD Ansatz, measurements are performed to compute its reduced density matrices (RDMs). Contributions are then written of broken-pair configurations as the correction to the upCCD wave function, and second-order perturbation theory is used to derive the energy correction. By plugging the measured RDM into the energy correction expression and add it to the upCCD energy, the accuracy of upCCD is improved.

The structure of upCCD Ansatz makes the RDM very sparse. Motivated by this, embodiments of the present disclosure provide an efficient algorithm that selects and measures the non-zero element of the upCCD RDMs. The algorithm provides two advantages. First, it does not increase the circuit depth of the upCCD, which makes it efficient to run on today's quantum computers. Second, it is not iterative, meaning that one does not need to deal with complicated parameter optimization using a classical optimizer. The present algorithm significantly improves the accuracy of upCCD to predict potential energy surfaces and energy barriers of a unimolecular decomposition reaction and improves the efficiency of Variational Quantum Eigensolver (VQE) calculation. It also offers an alternative solution to design new materials or chemicals using near-term quantum computers.

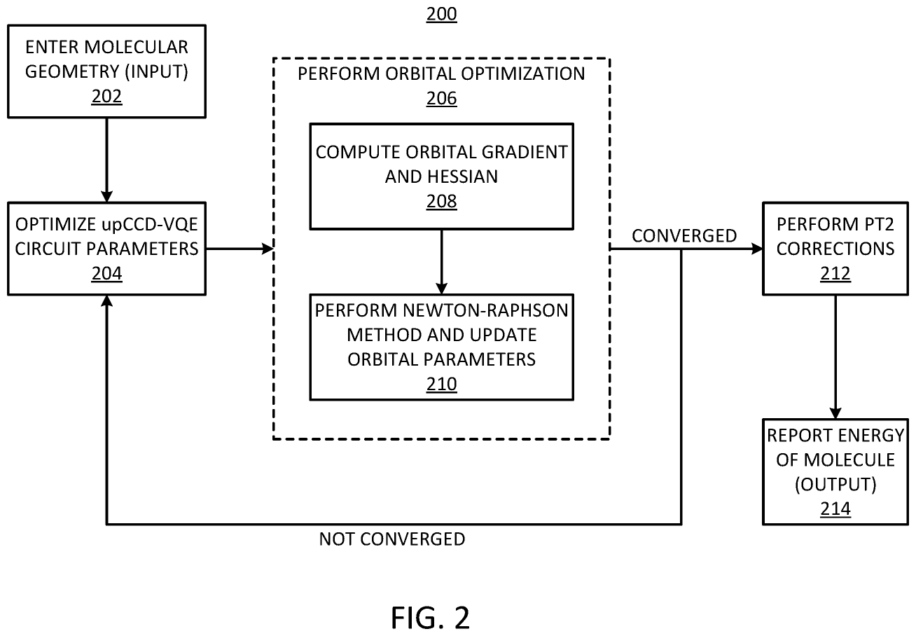

Referring now to FIG. 2, a method 200 for performing an algorithm to enhance the accuracy of electron pair (seniority-zero) approximation using non-bosonic perturbation (PT2) correction is illustratively depicted, in accordance with an exemplary embodiment of the present disclosure.

According to an exemplary embodiment, an approach is provided that improves the accuracy of upCCD based on measurements and second order perturbation theory (PT2). Starting from the upCCD Ansatz, measurements may be performed to compute its reduced density matrices (RDMs). Contributions of broken-pair configurations are then written as the correction to the upCCD wave function, and second-order perturbation theory (PT2) is used to derive the energy correction. By plugging the measured RDMs into the energy correction expression and adding it to the upCCD energy, the accuracy of the upCCD can be improved.

At 202, an upCCD Ansatz is generated of a molecule, and the molecular geometry (Cartesian coordinates) of the molecule is entered as the input of a VQE calculation.

The VQE is a variational method that finds an optimal solution by exchanging data between a quantum computer and a classical computer so as to simulate a quantum state (Ansatz) of a certain molecule and represent the qubit Ansatz quantum state with a quantum algorithm of a quantum computer for obtaining the ground state (an inherent energy state of a material) of a molecule. Here, the upCCD Ansatz is employed because one of the most efficient Ansatz for closed-shell molecules is upCCD due to its pair-approximation. At 204, a VQE simulation is run using upCCD Ansatz, and VQE circuit parameters are optimized.

At 206, orbital optimization is performed. According to an exemplary embodiment, orbital optimization may comprise, at 208, computing an orbital gradient and Hessian and, at 210, performing the Newton-Raphson method and updating the orbital parameters.

According to an exemplary embodiment, the orbital optimization method may comprise measuring one- and two-body reduced density matrices for the VQE circuit. The orbital optimization method may further comprise computing, as a function of the one- and two-body reduced density matrices, the energy gradient and Hessian with respect to the orbital rotation parameters. The orbital optimization method may further comprise performing a Newton-Raphson update to find a new set of orbital rotation parameters and rotating the one- and two-electron integrals based on the new set of orbital rotation parameters.

According to an exemplary embodiment, to prevent unphysical behavior and improve the accuracy of energy calculation in stretched geometry (e.g., bond length beyond the equilibrium position) of molecule, orbital optimization may comprise performing orbital optimization (00) until the energy of oo-upCCD is converged.

According to an exemplary embodiment, if the input geometries do not include any stretched geometries (e.g., when unphysical behavior effect is not significant), orbital optimization calculation may be optional.

According to an exemplary embodiment, once oo-upCCD (or upCCD) VQE calculation is converged, additional corrections, at 212, may be performed based on the second order perturbation theory (PT2) on the energy of oo-upCCD (or upCCD). The PT2 correction energy value, E (i.e., the total energy after the PT2 correction is applied), may be calculated by using Equation 1, and the PT2 correction energy term, E⁽²⁾, may be determined by Equation 2.

$$E = {E}_{upCCD - VQE} + {E}^{( 2 )} \qquad Equation 1$$

E_{upCCD-VQE} is the VQE energy without the PT2 correction and E⁽²⁾ is the PT2 energy correction. The PT2 correction energy term, E⁽²⁾, may be determined by Equation 2.

$${E}^{( 2 )} = {{\sum }^{non - pair}}_{P} {t}_{P} 〈 {Ψ}^{( 0 )} \vert V \vert {Ψ}_{P} 〉 \qquad Equation 2$$

The developed PT2 correction algorithm for upCCD-VQE does not increase the circuit depth. According to an exemplary embodiment, [symbol] Ψ⁽⁰⁾|V|Ψ_{P} [symbol] may be directly measured on quantum computers. It is noted, however, that other means for measuring [symbol] Ψ⁽⁰⁾|V|Ψ_{P} [symbol] may also be implemented, while maintaining the spirit and functionality of the present disclosure. According to an exemplary embodiment, amplitudes, tₚ, may be solved using Equation 3.

$$\vec{t} = - {G}^{- 1} \vec{Y} \qquad Equation 3$$

According to an exemplary embodiment, to solve for t, the inverse of G is computed and multiplied by Y. Variables G and Y may be computed using Equation 4 and Equation 5.

$${G}_{PG} = 〈 {Ψ}_{Q} \vert {H}_{0} \vert {Ψ}_{P} 〉 - {E}^{( 0 )} 〈 {Ψ}_{Q} \vert {Ψ}_{P} 〉 \qquad Equation 4$$

$${Y}_{P} = 〈 {Ψ}_{P} \vert V \vert {Ψ}^{( 0 )} 〉 \qquad Equation 5$$

According to an exemplary embodiment, variables G and Y may be measured on quantum computers. It is noted, however, that other means for measuring variables G and Y may also be implemented, while maintaining the spirit and functionality of the present disclosure. According to an exemplary embodiment, performing the additional corrections may comprise measure and/or calculating variables G and Y using quantum computers, solving for t using Equation 3, computing E⁽²⁾ using Equation 2, and then computing the total energy, E, using Equation 1.

Equation 3 could run into numerical instabilities when the variable G is close to zero. In order to remove the instability, Equation 3 is regularized by

$${t}_{p} = - \frac{{Y}_{p}}{{G}_{pp}} ( 1 - {e}^{- σ {G}_{pp}} ) .$$

This can make that t goes to zero if G is close to zero.

At 214, the corrected VQE energy of the input molecule (output) may be reported. According to an exemplary embodiment, the corrected VQE energy of the input molecule may be reported to a user, to a third party device, and/or to one or more other suitable users and/or devices. The corrected VQE simulation results may be used to study or develop a new molecular structure for the chemical reactions, batteries, catalysts, chemical informatics, etc.

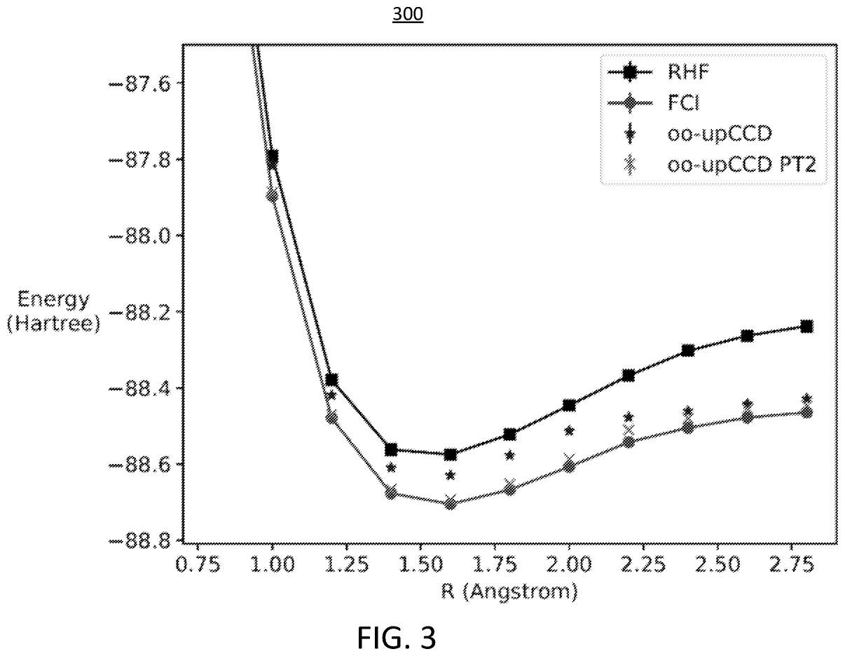

Referring now to FIG. 3, a graphical representation 300 of dissociation of Li₂O is illustratively depicted, in accordance with an exemplary embodiment of a practical example of the present disclosure.

According to the practical example of the present disclosure as shown in FIG. 3, symmetric dissociation of the Li₂O molecule is measured. Li₂O is one of the secondary reaction products in lithium-air batteries, which is a candidate for next-generation battery due to its high energy density. FIG. 3 shows the calculation result of the prior VQE algorithm (oo-upCCD) and the developed algorithm (oo-puCCD PT2), the theoretical value (FCI), and the restricted Hartree Fock (RHF) mean-field energy.

The difference in energy between oo-upCCD and theoretical value (FCI) became noticeable in Li₂O dissociation energy prediction due to the seniority-zero (pair) approximation. As is shown, PT2 correction significantly improves the accuracy of oo-upCCD, and brings the energy much closer to the prediction of FCI.

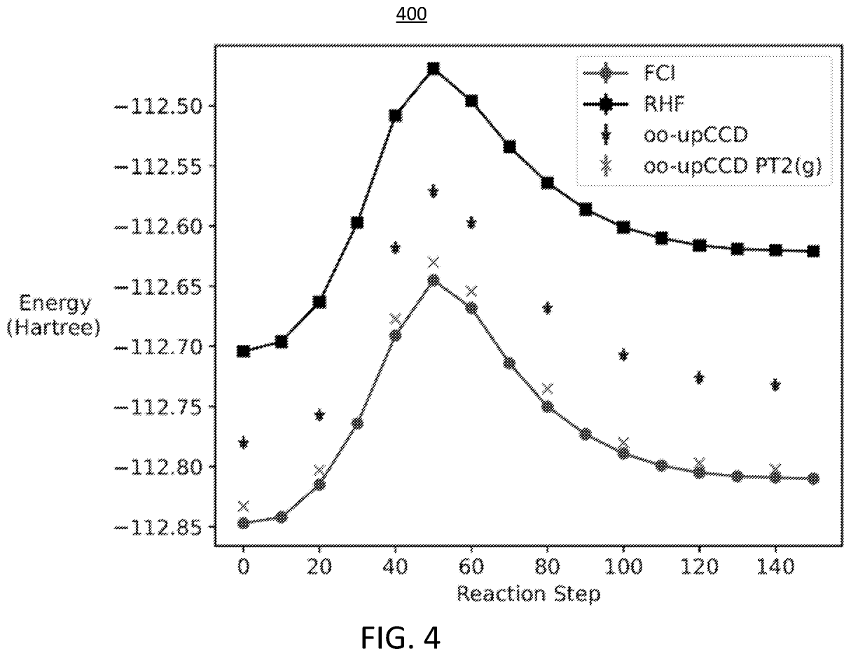

Referring now to FIG. 4, a graphical representation 400 of CH₂OH⁺→HCO⁺+H₂ reaction energy prediction is illustratively depicted, in accordance with an exemplary embodiment of a practical example of the present disclosure.

According to the practical example of the present disclosure as shown in FIG. 4, the chemical decomposition process of the CH₂OH⁺→HCO⁺+H₂ reaction was performed. FIG. 4 shows the calculation result of the prior VQE algorithm (oo-upCCD) and the developed algorithm (oo-puCCD PT2), the theoretical value (FCI), and the restricted Hartree Fock (RHF) mean-field energy.

Similar to the Li₂O dissociation energy calculation, PT2 correction significantly improves the error of oo-upCCD, and brings the energy much closer to the prediction of the theoretical value (FCI).

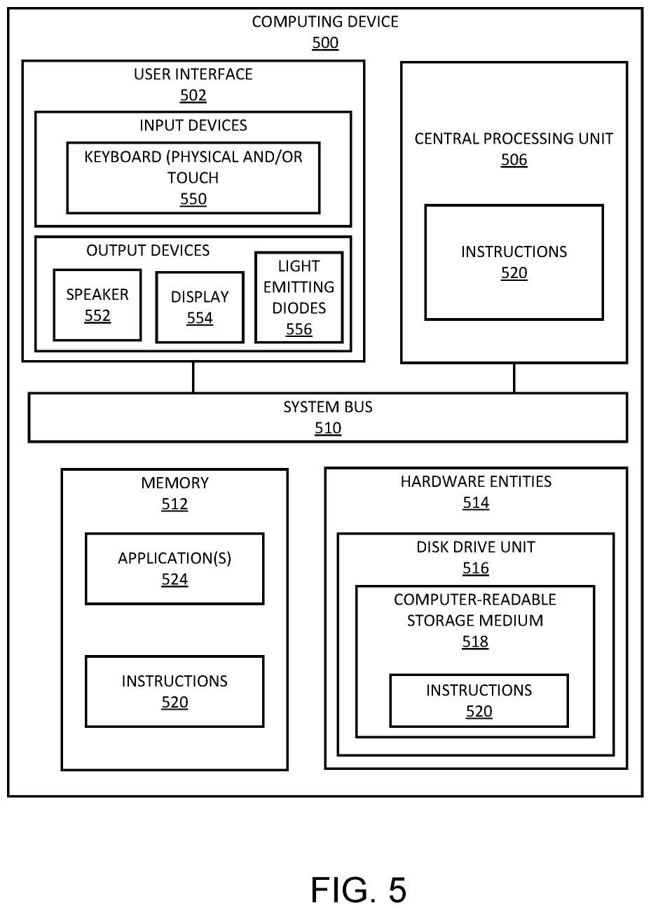

Referring now to FIG. 5, an illustration of an example architecture for a computing device 500 is provided. According to an exemplary embodiment, one or more functions of the present disclosure may be implemented by a computing device such as, e.g., computing device 500 or a computing device similar to computing device 500. Computing device 500 may be a quantum computer, a classical computer, and/or have one or more components configured to perform one or more quantum and/or classical computing functions.

The hardware architecture of FIG. 5 represents one example implementation of a representative computing device configured to perform one or more methods for performing an algorithm to enhance the accuracy of electron pair (seniority-zero) approximation using non-bosonic perturbation (PT2) correction, as described herein. As such, the computing device 500 of FIG. 5 may be configured to implement at least a portion of the method(s) described herein (e.g., method 200 of FIG. 2).

Some or all components of the computing device 500 may be implemented as hardware, software, and/or a combination of hardware and software. The hardware may comprise, but is not limited to, one or more electronic circuits. The electronic circuits may comprise, but are not limited to, passive components (e.g., resistors and capacitors) and/or active components (e.g., amplifiers and/or microprocessors). The passive and/or active components may be adapted to, arranged to, and/or programmed to perform one or more of the methodologies, procedures, or functions described herein.

As shown in FIG. 5, the computing device 500 may comprise a user interface 502 (e.g., a graphical user interface), a Central Processing Unit (“CPU”) 506, a system bus 510, a memory 512 connected to and accessible by other portions of computing device 500 through system bus 510, and hardware entities 514 connected to system bus 510. The user interface may comprise input devices and output devices, which may be configured to facilitate user-software interactions for controlling operations of the computing device 500. The input devices may comprise, but are not limited to, a physical and/or touch keyboard 540. The input devices may be connected to the computing device 500 via a wired or wireless connection (e.g., a Bluetooth® connection). The output devices may comprise, but are not limited to, a speaker 542, a display 544, and/or light emitting diodes 546.

At least some of the hardware entities 514 may be configured to perform actions involving access to and use of memory 512, which may be a Random Access Memory (RAM), a disk driver and/or a Compact Disc Read Only Memory (CD-ROM), among other suitable memory types. Hardware entities 514 may comprise a disk drive unit 516 comprising a computer-readable storage medium 518 on which may be stored one or more sets of instructions 520 (e.g., programming instructions such as, but not limited to, software code) configured to implement one or more of the methodologies, procedures, or functions described herein. The instructions 520 may also reside, completely or at least partially, within the memory 512 and/or within the CPU 506 during execution thereof by the computing device 500.

The memory 512 and the CPU 506 may also constitute machine-readable media. The term “machine-readable media”, as used here, refers to a single medium or multiple media (e.g., a centralized or distributed database, and/or associated caches and servers) that store the one or more sets of instructions 520. The term “machine-readable media”, as used here, also refers to any medium that is capable of storing, encoding, or carrying a set of instructions 520 for execution by the computing device 500 and that cause the computing device 500 to perform any one or more of the methodologies of the present disclosure.

What has been described above includes examples of the subject disclosure. It is, of course, not possible to describe every conceivable combination of components or methodologies for purposes of describing the subject matter, but it is to be appreciated that many further combinations and permutations of the subject disclosure are possible. Accordingly, the claimed subject matter is intended to embrace all such alterations, modifications, and variations that fall within the spirit and scope of the appended claims.

In particular and in regard to the various functions performed by the above described components, devices, systems and the like, the terms (including a reference to a “means”) used to describe such components are intended to correspond, unless otherwise indicated, to any component which performs the specified function of the described component (e.g., a functional equivalent), even though not structurally equivalent to the disclosed structure, which performs the function in the herein illustrated exemplary aspects of the claimed subject matter.

The aforementioned systems and components have been described with respect to interaction between several components. It can be appreciated that such systems and components can include those components or specified sub-components, some of the specified components or sub-components, and/or additional components, and according to various permutations and combinations of the foregoing. Sub-components can also be implemented as components communicatively coupled to other components rather than included within parent components (hierarchical). Additionally, it should be noted that one or more components may be combined into a single component providing aggregate functionality or divided into several separate sub-components. Any components described herein may also interact with one or more other components not specifically described herein.

In addition, while a particular feature of the subject innovation may have been disclosed with respect to only one of several implementations, such feature may be combined with one or more other features of the other implementations as may be desired and advantageous for any given or particular application. Furthermore, to the extent that the terms “includes,” “including,” “has,” “contains,” variants thereof, and other similar words are used in either the detailed description or the claims, these terms are intended to be inclusive in a manner similar to the term “comprising” as an open transition word without precluding any additional or other elements.

Thus, the embodiments and examples set forth herein were presented in order to best explain various selected embodiments of the present disclosure and its particular application and to thereby enable those skilled in the art to make and use embodiments of the present disclosure. However, those skilled in the art will recognize that the foregoing description and examples have been presented for the purposes of illustration and example only. The description as set forth is not intended to be exhaustive or to limit the embodiments of the present disclosure to the precise form disclosed.

What is claimed is:

1. A method for enhancing accuracy of electron pair approximation using non-bosonic perturbation (PT2) correction, comprising:
generating a unitary pair coupled cluster double (upCCD) Ansatz to determine geometry coordinates of a molecule;
inputting, using a graphical user interface, the geometry coordinates of the molecule;
performing, using a processor of a computing device comprising the processor and a memory, orbital optimization to generate an orbital optimization upCCD (oo-upCCD) comprising an energy calculation; and
performing, using the processor, energy correction on the energy calculation of the oo-upCCD based on a second order perturbation theory (PT2), generating a PT2 correction energy value of the molecule.

2. The method of claim 1, further comprising, using the processor, reporting the PT2 correction energy value of the molecule.

3. The method of claim 1, wherein the performing the orbital optimization comprises computing an orbital gradient and a Hessian.

4. The method of claim 3, wherein the performing the orbital optimization comprises:
performing a Newton-Raphson method; and
updating one or more orbital parameters.

5. The method of claim 1, wherein the performing the orbital optimization comprises performing the orbital optimization until the energy calculation of the oo-upCCD is converged.

6. The method of claim 1, wherein the computing device comprises a quantum computer.

7. A system for enhancing accuracy of electron pair approximation using non-bosonic perturbation (PT2) correction, comprising:
a computing device, comprising:
a processor;
a memory; and
a graphical user interface,
wherein:
the processor is configured to generate a unitary pair coupled cluster double (upCCD) Ansatz to determine geometry coordinates of a molecule,
the graphical user interface is configured to receive, as input, the geometry coordinates of the molecule, and
the processor is further configured to:
perform orbital optimization to generate an orbital optimization upCCD (oo-upCCD) comprising an energy calculation; and
perform energy correction on the energy calculation of the oo-upCCD based on a second order perturbation theory (PT2), generating a PT2 correction energy value of the molecule.

8. The system of claim 7, wherein the processor is further configured to report the PT2 correction energy value of the molecule.

9. The system of claim 7, wherein the processor, in performing the orbital optimization, is configured to compute an orbital gradient and a Hessian.

10. The system of claim 9, wherein the processor, in performing the orbital optimization, is configured to:
perform a Newton-Raphson method; and
update one or more orbital parameters.

11. The system of claim 7, wherein the processor, in performing the orbital optimization, is configured to perform the orbital optimization until the energy calculation of the oo-upCCD is converged.

12. The system of claim 7, wherein the computing device comprises a quantum computer.

13. A system for enhancing accuracy of electron pair approximation using non-bosonic perturbation (PT2) correction, comprising:
a computing device, comprising:
a processor;
a memory; and
a graphical user interface,
wherein the memory is configured to store programming instructions that, when executed by the processor, are configured to cause the processor to:
generate a unitary pair coupled cluster double (upCCD) Ansatz to determine geometry coordinates of a molecule;
enable the graphical user interface to receive, as input, the geometry coordinates of the molecule;
perform orbital optimization to generate an orbital optimization upCCD (oo-upCCD) comprising an energy calculation; and
perform energy correction on the energy calculation of the oo-upCCD based on a second order perturbation theory (PT2), generating a PT2 correction energy value of the molecule.

14. The system of claim 13, wherein the programming instructions, when executed by the processor, are further configured to cause the processor to report the PT2 correction energy value of the molecule.

15. The system of claim 13, wherein the programming instructions, when executed by the processor, are further configured to cause the processor, in performing the orbital optimization, to compute an orbital gradient and a Hessian.

16. The system of claim 15, wherein the programming instructions, when executed by the processor, are further configured to cause the processor, in performing the orbital optimization, to:
perform a Newton-Raphson method; and
update one or more orbital parameters.

17. The system of claim 13, wherein the programming instructions, when executed by the processor, are further configured to cause the processor, in performing the orbital optimization, to perform the orbital optimization until the energy calculation of the oo-upCCD is converged.

18. The system of claim 13, wherein the computing device comprises a quantum computer.
